(19) United States
(12) Patent Application Publication
(10) Pub. No.: US 2026/0169533 A1
(43) Pub. Date: Jun. 18, 2026

(54) DEVICE COOLING SYSTEM

(71) Applicant: QUALCOMM Incorporated, San Diego, CA (US)

(72) Inventors: Peng WANG, San Diego, CA (US); Youmin YU, Escondido, CA (US); Nader NIKFAR, San Diego, CA (US); Mario SANCHEZ, San Diego, CA (US); Vineeth BHARADWAJ, San Diego, CA (US)

(21) Appl. No.: 18/984,422

(22) Filed: Dec. 17, 2024

(51) Int. Cl. G06F 1/20; H05K 7/20

(52) U.S. Cl. CPC G06F 1/203; H05K 7/20136; H05K 7/20272

(57) ABSTRACT

A device includes a first portion, a second portion moveably coupled to the first portion via a junction, and a cooling loop structure. The cooling loop structure includes a fluid transport structure and a fluid driving structure coupled to the fluid transport structure. The fluid driving structure is configured to move a fluid through the fluid transport structure. The fluid transport structure extends into the first portion, into the second portion, and across the junction to enable heat distribution between the first portion and the second portion.

### FIELD

Various features relate to thermal management in devices.

### BACKGROUND

State-of-the-art mobile application devices demand a small form factor, low cost, a tight power budget, and high electrical performance. Mobile package design has evolved to meet these divergent goals for enabling mobile applications that support multimedia enhancements. These mobile application devices, however, are susceptible to uneven heating and overheating with multiple heat sources arranged within the small form factor. Additionally, more complex form factors, such as foldable devices, can create scenarios in which thermal management across the entirety of the form factor is increasingly difficult.

### SUMMARY

Various features relate to thermal management in devices.

One example provides a device that includes a first portion, a second portion moveably coupled to the first portion via a junction, and a cooling mechanism. The cooling mechanism includes a fluid transport structure and a fluid driving structure coupled to the fluid transport structure. The fluid driving structure is configured to move a fluid through the fluid transport structure. The fluid transport structure extends into the first portion, into the second portion, and across the junction to enable heat distribution between the first portion and the second portion.

Another example provides a cooling loop structure that includes a fluid transport structure and a fluid driving structure coupled to the fluid transport structure and configured to move a fluid through the fluid transport structure. The fluid transport structure includes a first fluid transport portion configured to be positioned in a first portion of a device, a second fluid transport portion configured to be positioned in a second portion of the device, wherein the second portion is moveably coupled to the first portion via a junction, and a third fluid transport portion configured to be positioned in the junction.

Another example provides a method that includes forming a fluid transport structure and forming a fluid driving structure coupled to the fluid transport structure and configured to move a fluid through the fluid transport structure. The fluid transport structure includes a first fluid transport portion configured to be positioned in a first portion of a device, and a second fluid transport portion configured to be positioned in a second portion of the device. The second portion is moveably coupled to the first portion via a junction. The fluid transport structure also includes a third fluid transport portion configured to be positioned in the junction.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a first exemplary device cooling system that includes a device with a first portion and a second portion moveably coupled to the first portion via a junction.

FIG. 2 illustrates a second exemplary device cooling system that includes the device with the first portion and the second portion moveably coupled to the first portion via the junction.

FIG. 3 illustrates a third exemplary device cooling system that includes the device with the first portion and the second portion moveably coupled to the first portion via the junction.

FIG. 4A illustrates a cross-sectional view of an exemplary device that includes a fluid transport structure.

FIG. 4B illustrates another cross-sectional view of an exemplary device that includes the fluid transport structure.

FIG. 4C illustrates another cross-sectional view of an exemplary device that includes the fluid transport structure.

FIG. 5 illustrates an exemplary flow diagram of a method for providing or fabricating a device cooling system.

FIG. 6 illustrates various electronic devices that may include or be integrated with a device that includes a device cooling system such as any of the device cooling systems described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified herein to highlight important features of the disclosure without unduly complicating the drawings

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

State-of-the-art mobile application devices demand a small form factor, low cost, a tight power budget, and high electrical performance. Mobile package design has evolved to meet these divergent goals for enabling mobile applications that support multimedia enhancements. For example, a mobile application device can include multiple antenna modules and a system-on-chip (SoC) that includes one or more processors. These mobile applications, however, are susceptible to overheating issues when multiple heat sources (e.g., the antenna modules and SoC) are arranged within the small form factor. Additionally, more complex form factors, such as foldable devices, can create scenarios in which thermal management across the entirety of the form factor is increasingly difficult.

Various aspects of the present disclosure provide a device cooling system that includes a fluid driving structure coupled to a fluid transport structure. The fluid transport structure includes multiple portions that can extend across all or substantially all of more complex form factors, such as those for foldable devices, resulting in improved thermal distribution for such devices.

### Exemplary Systems Including a Cooling Loop Structure

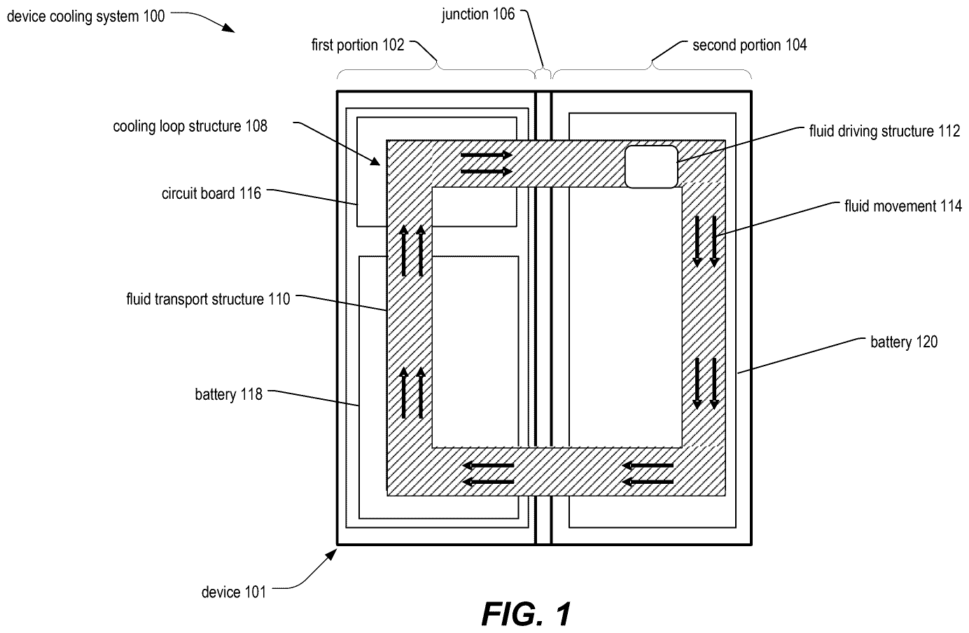

FIG. 1 illustrates a particular implementation of a device cooling system 100 that includes a device 101 with a first portion 102 and a second portion 104 moveably coupled to the first portion 102 via a junction 106. In some aspects, the device 101 corresponds to a foldable device. For example, the foldable device can be configured such that the second portion 104 is foldably coupled to the first portion 102 via the junction 106. The foldable device can include, for example, a smartphone. In a particular aspect such as a smartphone implementation, the device 101 can also include a foldable display coupled to the first portion 102 and the second portion 104.

The device 101 can include one or more heat-generating components distributed across the first portion 102 and the second portion 104. In a particular aspect, the device 101 includes a circuit board 116 and a battery 118 within the first portion 102, and a battery 120 within the second portion 104. In the same or alternative aspects, more, fewer, and/or different components can be present within the device 101 without departing from the scope of the subject disclosure.

The component(s) of the device 101 generate heat as part of the operation of the device 101. In a particular aspect, components within a portion of the device 101 can generate relatively greater heat than components within another portion of the device 101. For example, if the first portion 102 of the device 101 includes the circuit board 116 and the battery 118, and the second portion 104 of the device 101 includes the battery 120, the first portion 102 can generate more heat than the second portion 104 during operation of the device 101.

In some implementations, the device 101 includes a cooling loop structure 108. The cooling loop structure 108 is a component internal to the device 101 configured to distribute heat across a plurality of portions of the device 101. In a particular aspect, the cooling loop structure 108 can be configured to distribute at least some of the heat from one portion of the device 101 to another portion of the device 101. Using the example above, the cooling loop structure 108 can be configured to distribute at least some of the heat from the first portion 102 of the device 101 to the second portion 104 of the device 101.

The cooling loop structure 108 includes a fluid transport structure 110 coupled to a fluid driving structure 112. The fluid driving structure 112 is configured to move a fluid through the fluid transport structure 110. The fluid can include, for example, atmospheric air, a non-gaseous fluid (e.g., a heat retention liquid), or a combination thereof. The fluid transport structure 110 extends into the first portion 102, the second portion 104, and across the junction 106 to enable heat distribution between the first portion 102 and the second portion 104. Using the example above, the cooling loop structure 108 can be configured to distribute at least some of the heat from the first portion 102 to the second portion 104 via movement of the fluid through the fluid transport structure 110.

The fluid driving structure 112 can be configured to move the fluid through the fluid transport structure 110 (e.g., in the direction of fluid movement 114 illustrated by arrows). For example, the fluid driving structure 112 can include one or more fluid pump components configured to move the fluid through the fluid transport structure 110. The component(s) can be internal to the fluid transport structure 110, external to the fluid transport structure 110, or a combination thereof. The component(s) can include, for example, an air pump, a water pump, micro/mini-fan, micro/mini-blower, piezoelectric air mover, micro water pump, piezoelectric-based liquid pump etc.

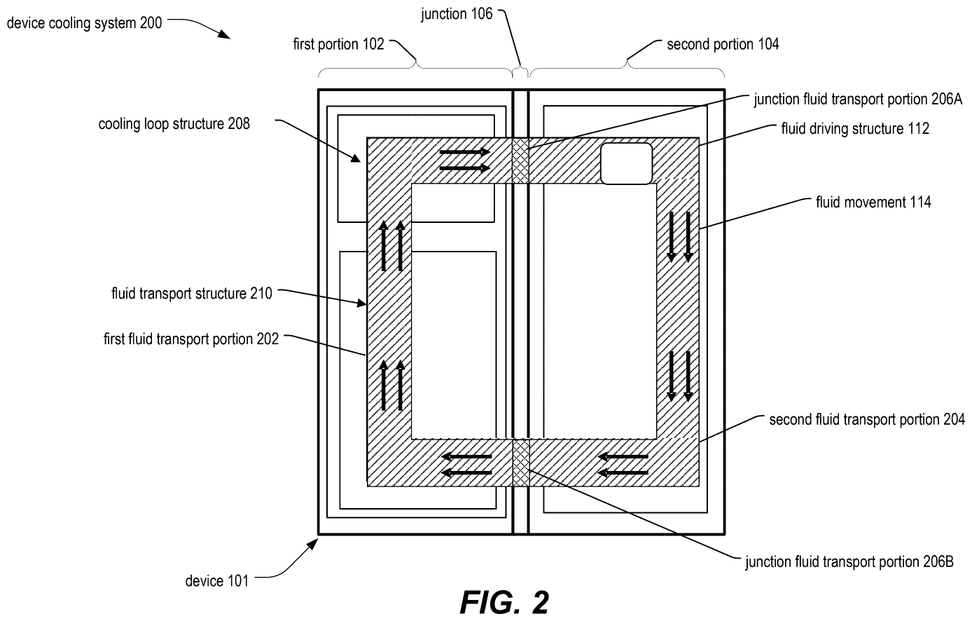

To provide the heat transfer across the junction 106, the fluid transport structure 110 is formed of a flexible material at least at that portion of the fluid transport structure 110 that extends across the junction 106. In some aspects, only a portion of the fluid transport structure 110 is formed of the flexible material, as described in more detail below with reference to FIG. 2. In other aspects, additional portions (including the entirety) of the fluid transport structure 110 can be formed of the flexible material. For example, the fluid transport structure 110 can be formed substantially from plastic. In a particular aspect, the fluid transport structure 110 can be formed in a relatively hollow, tubular shape. For example, the fluid transport structure 110 can be approximately 5-20 millimeters (mm) wide and have a total thickness of approximately 0.5-2 mm.

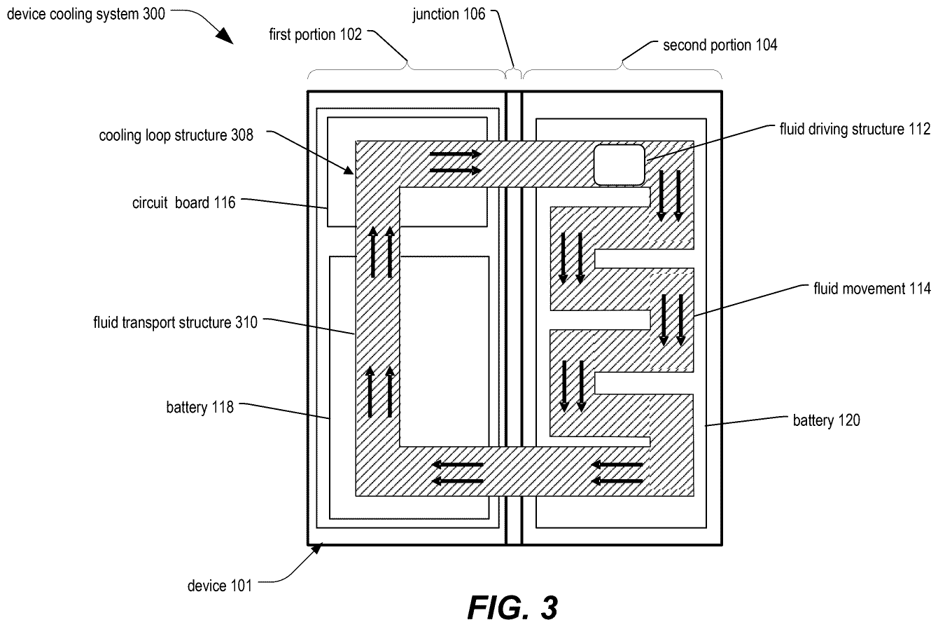

In some implementations, the fluid transport structure 110 can be formed in a substantially continuous loop, as illustrated in FIG. 1. In other implementations, the fluid transport structure 110 can be formed in other shapes that enable increased heat distribution across a portion of the device 101. For example, as described and illustrated with reference to FIG. 3, the fluid transport structure can be formed in a shape that includes a plurality of turns through a relatively lower-heat portion of the device 101. In some aspects, the fluid transport structure 110 provides a path for the fluid from the first portion 102 to the second portion 104 and also provides a return path for the fluid from the second portion 104 to the first portion 102, enabling circulation of the fluid throughout the device 101.

As an exemplary operation, the device 101 can be a foldable device such as a smartphone. The device 101 can include a foldable display coupled to the first portion 102 of the device 101 and to the second portion 104 of the device 101. The device 101 can also include a cooling loop structure 108 that includes the fluid transport structure 110 that extends into the first portion 102, into the second portion 104, and across the junction 106 coupling the first portion 102 to the second portion 104. The first portion 102 includes a main circuit board (e.g., the circuit board 116) and the battery 118. The second portion includes the battery 120. The components within the first portion 102 generate relatively more heat than the components within the second portion 104. The cooling loop structure 108 includes the fluid driving structure 112 configured to move the fluid in the direction of the fluid movement 114 through the fluid transport structure 110, enabling heat distribution from the first portion 102, across the junction 106, and through the second portion 104. The improved heat distribution enables the device 101 to operate more efficiently, with relatively less overheating of the components within the first portion 102 (e.g., the main circuit board). In such an exemplary configuration, the foldable display can also be coupled to the fluid transport structure 110.

FIG. 2 illustrates another particular implementation of a device cooling system 200 that includes the device 101 with the first portion 102 and the second portion 104 moveably coupled to the first portion 102 via the junction 106. In some implementations, the device 101 includes a cooling loop structure 208. In a particular aspect, the cooling loop structure 208 can be configured to distribute at least some of the heat from one portion of the device 101 to another portion of the device 101. For example, the cooling loop structure 208 can be configured to distribute at least some of the heat from the first portion 102 of the device 101 to the second portion 104 of the device 101.

The cooling loop structure 208 includes a fluid transport structure 210 coupled to the fluid driving structure 112. The fluid driving structure 112 is configured to move a fluid through the fluid transport structure 210. The fluid can include, for example, atmospheric air, a non-gaseous fluid (e.g., a heat retention liquid), or a combination thereof. The fluid transport structure 210 extends into the first portion 102, the second portion 104, and across the junction 106 to enable heat distribution between the first portion 102 and the second portion 104.

The fluid transport structure 210 includes a first fluid transport portion 202 substantially within the first portion 102, a second fluid transport portion 204 substantially within the second portion 104, and a junction fluid transport portion 206 substantially within the junction 106. As described above with reference to FIG. 1, the fluid transport structure 210 can be formed partially or completely of a flexible material such as plastic. In the example of FIG. 2, the junction fluid transport portion 206 of the fluid transport structure 210 is formed of the flexible material. In some aspects, the rest of the fluid transport structure 210 is formed of a different material that may be more rigid than the material of the junction fluid transport portion 206 and may be selected based on one or more factors such as durability, size, cost, thermal properties, etc. In a particular aspect, the fluid transport structure 210 can be approximately 5-20 mm wide and approximately 0.5-2 mm thick.

The junction fluid transport portion 206 can include separate portions of the fluid transport structure 210 that can extend across the junction 106 at different locations. For example, the junction fluid transport portion 206 can include junction fluid transport portion 206A extending across the junction 106 at a first location and junction fluid transport portion 206B extending across the junction 106 at a second location.

FIG. 3 illustrates another particular implementation of a device cooling system 300 that includes the device 101 with the first portion 102 and the second portion 104 moveably coupled to the first portion 102 via the junction 106. In some implementations, the device 101 includes a cooling loop structure 308. In a particular aspect, the cooling loop structure 308 can be configured to distribute at least some of the heat from one portion of the device 101 to another portion of the device 101. For example, the cooling loop structure 308 can be configured to distribute at least some of the heat from the first portion 102 of the device 101 to the second portion 104 of the device 101.

The cooling loop structure 308 includes a fluid transport structure 310 coupled to the fluid driving structure 112. The fluid driving structure 112 is configured to move a fluid through the fluid transport structure 310. The fluid can include, for example, atmospheric air, a non-gaseous fluid (e.g., a heat retention liquid), or a combination thereof. The fluid transport structure 310 extends into the first portion 102, the second portion 104, and across the junction 106 to enable heat distribution between the first portion 102 and the second portion 104. In the example of FIG. 3, the fluid transport structure 310 includes a plurality of bends or turns within the second portion 104. The bends or turns provide relatively greater surface area of the fluid transport structure 310 to thermally contact the second portion 104 of the device 101. The increased surface area can enable greater heat distribution throughout the second portion 104, thus enabling greater heat distribution from the first portion 102 to the second portion 104.

As described above with reference to FIGS. 1 and 2, the fluid transport structure 310 can be formed partially or completely from a flexible material such as plastic. In a particular aspect, the fluid transport structure 310 can be approximately 5-20 mm wide and approximately 0.5-2 mm thick. For example, the fluid transport structure 310 can be formed entirely of the flexible material, include portions formed of the flexible material (e.g., those portions extending across the junction 106), etc.

Although the exemplary device cooling systems of FIGS. 1-3 illustrate certain components and configurations, other configurations are possible without departing from the scope of the subject disclosure. For example, each portion of the device 101 can include more, fewer, and/or different components than those illustrated in FIGS. 1-3. As another example, the designations of the first portion 102 and the second portion 104 are relatively arbitrary and can be switched without departing from the scope of the subject disclosure. As a further example, the second portion 104 of the device 101 can be configured to generate relatively more heat than the first portion 102 of the device 101, and the cooling loop structure can be configured to enable heat distribution from the second portion 104 to the first portion 102 (e.g., by including a plurality of bends or turns in the portion of the fluid transport structure included in the first portion 102). As a still further example, the device 101 can include more than two portions. Additional portions may be foldably or non-foldably coupled to the first portion 102, the second portion 104, or both.

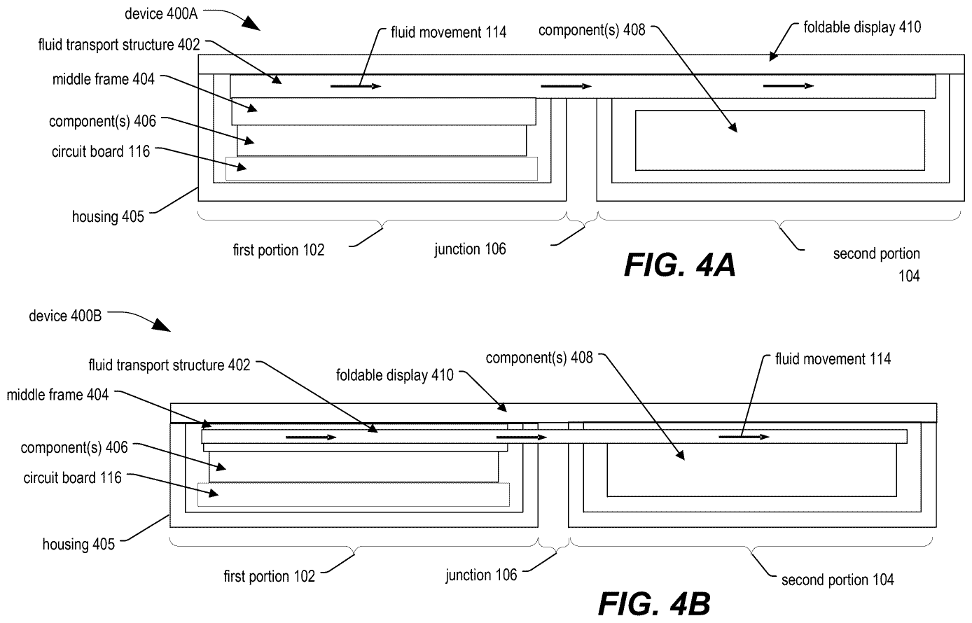

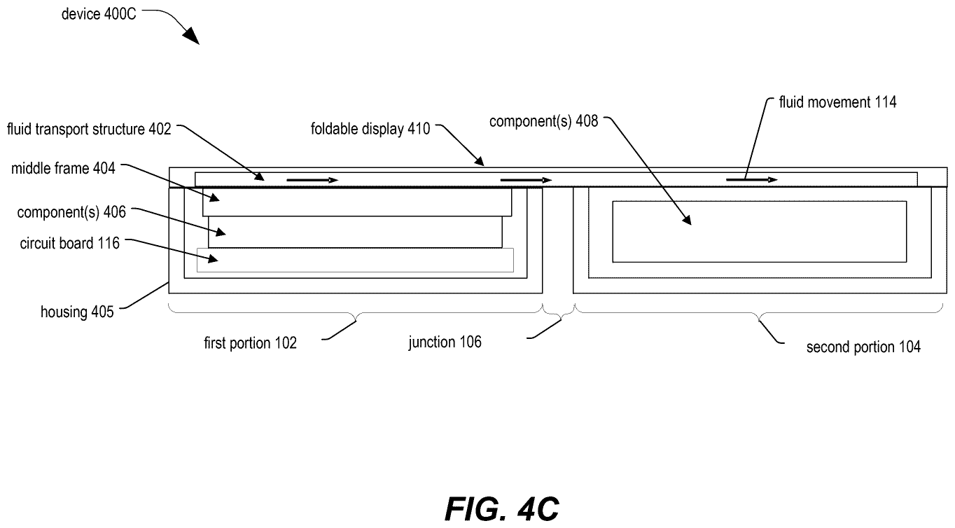

FIG. 4A illustrates a cross-sectional view of a device 400A that includes a fluid transport structure 402. Generally, the device 400A corresponds to the device 101 of FIGS. 1-3, and the fluid transport structure 402 can correspond to one or more of the fluid transport structures 110, 210, 310 of FIGS. 1-3. In the example of FIG. 4A, the device 400A includes the first portion 102 coupled to the second portion 104 via the junction 106 within a housing 405. The device 400A also includes a foldable display 410 coupled to the first portion 102, the second portion 104, and the fluid transport structure 402.

The first portion 102 of the device 400A includes the circuit board 116, one or more components 406 coupled to the circuit board 116, and a middle frame 404 coupled to the component(s) 406. The component(s) 406 can include, for example, the battery 118 of FIG. 1. The middle frame 404 can be a structural component included in the first portion 102 to support the fluid transport structure 402 and/or other components of the device 400A. In a particular aspect, the middle frame 404 is composed substantially of aluminum. In other aspects, the middle frame 404 can be composed partially or completely of other metal alloys. In the example of FIG. 4A, the fluid transport structure 402 is coupled to a surface of the middle frame 404.

The second portion 104 of the device 400A includes one or more components 408. The component(s) 408 can include, for example, the battery 120 of FIG. 1, the fluid driving structure 112, etc. As described in more detail above with reference to FIGS. 1-3, the fluid transport structure 402 can be configured to contain a fluid moving through the fluid transport structure 402 (e.g., in the direction of the fluid movement 114) to enable heat distribution from the first portion 102 to the second portion 104.

FIG. 4B illustrates another cross-sectional view of a device 400B that includes the fluid transport structure 402. Generally, the device 400B corresponds to the device 101 of FIGS. 1-3 and includes the foldable display 410. In the example of FIG. 4B, a portion of the fluid transport structure 402 is embedded within the middle frame 404. The fluid transport structure 402 extends through the first portion 102, through the second portion 104, and across the junction 106 within the housing 405. The fluid transport structure 402 enables movement of the fluid (e.g., in the direction of the fluid movement 114) through the device 400B, providing for heat distribution between the first portion 102 and the second portion 104 (e.g., between the component(s) 406, the circuit board 116, and the component(s) 408).

FIG. 4C illustrates another cross-sectional view of a device 400C that includes the fluid transport structure 402. Generally, the device 400C corresponds to the device 101 of FIGS. 1-3 and includes the foldable display 410. In the example of FIG. 4C, the fluid transport structure 402 is embedded wholly or partially within the foldable display 410, which is coupled to the middle frame 404. The fluid transport structure 402 extends through the first portion 102, through the second portion 104, and across the junction 106 within the housing 405. The fluid transport structure 402 enables movement of the fluid (e.g., in the direction of the fluid movement 114) through the device 400C, providing for heat distribution between the first portion 102 and the second portion 104 (e.g., between the component(s) 406, the circuit board 116, and the component(s) 408).

### Exemplary Flow Diagram of a Method for Fabricating a Device Cooling System

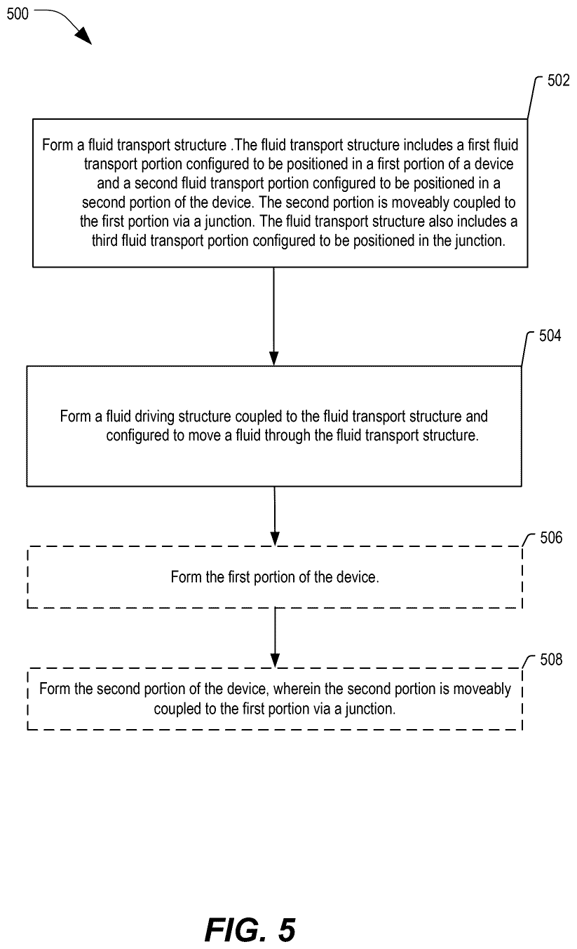

In some implementations, fabricating a device cooling system includes several processes. FIG. 5 illustrates an exemplary flow diagram of a method 500 for providing or fabricating a device cooling system. In some implementations, the method 500 of FIG. 5 may be used to provide or fabricate the device cooling system 100 of FIG. 1, the device cooling system 200 of FIG. 2, the device cooling system 300 of FIG. 3, or a combination thereof.

It should be noted that the method 500 of FIG. 5 may combine one or more processes in order to simplify and/or clarify the method for providing or fabricating a device cooling system. In some implementations, the order of the processes may be changed or modified.

The method 500 includes, at block 502, forming a fluid transport structure. The fluid transport structure includes a first fluid movement portion configured to be positioned in a first portion of a device and a second fluid movement portion configured to be positioned in a second portion of the device. The second portion is moveably coupled to the first portion via a junction. The fluid transport structure also includes a third fluid movement portion configured to be positioned in the junction. For example, a flexible material such as plastic can be formed in a shape corresponding to the fluid transport structure 110 of FIG. 1, the fluid transport structure 210 of FIG. 2, the fluid transport structure 310 of FIG. 3, the fluid transport structure 402 of FIGS. 4A-4C, or a combination thereof.

The method 500 includes, at block 504, forming a fluid driving structure coupled to the fluid transport structure and configured to move a fluid through the fluid transport structure. For example, a fluid pump can be formed and coupled to the fluid transport structure. The fluid pump can be configured to move the fluid (e.g., atmospheric air) through the fluid transport structure. The fluid driving structure corresponds to the fluid driving structure 112 of FIGS. 1-3.

In some implementations, the method 500 can include additional processes. For example, the method 500 can also include, at block 506, forming the first portion of the device. For example, a smartphone manufacturing process can include forming a first portion of the smartphone. The first portion of the device corresponds to the first portion 102 of the device 101 of FIGS. 1-3, the first portion 102 of the device 400 of FIGS. 4A-4C, or a combination thereof.

The method 500 can also include, at block 508, forming the second portion of the device, wherein the second portion is moveably coupled to the first portion via a junction. For example, a smartphone manufacturing process can include forming a second portion of the smartphone moveably coupled to the first portion via a junction. The second portion of the device corresponds to the second portion 104 of the device 101 of FIGS. 1-3, the second portion 104 of the device 400 of FIGS. 4A-4C, or a combination thereof.

### Exemplary Electronic Devices

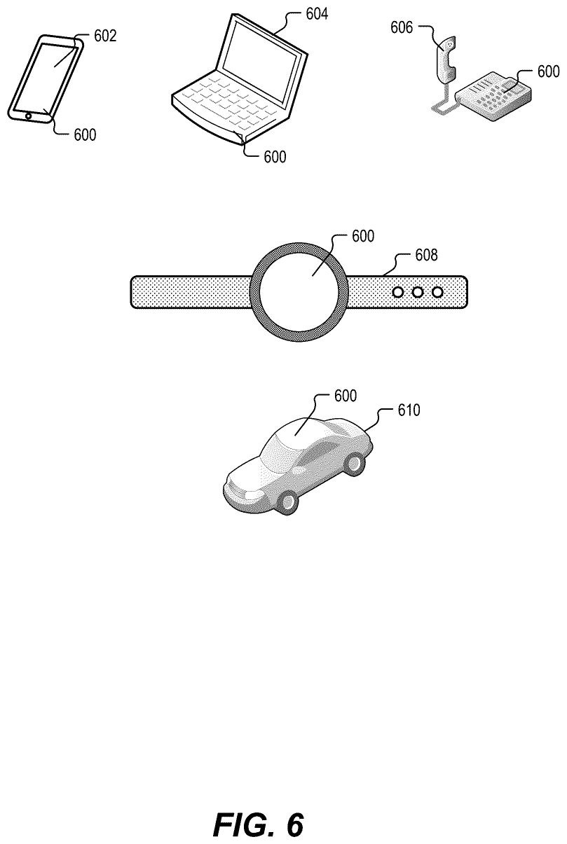

FIG. 6 illustrates various electronic devices that may include or be integrated with a device 600 that includes a device cooling system, such as any of the device cooling systems 100, 200, or 300. For example, a mobile phone device 602, a laptop computer device 604, a fixed location terminal device 606, a wearable device 608, or a vehicle 610 (e.g., an automobile or an aerial device) may include a device 600. The device 600 can include, for example, the device 101 of FIGS. 1-3, the device 400 of FIGS. 4A-4C, or a combination thereof, as described herein. The devices 602, 604, 606, and 608, and the vehicle 610 illustrated in FIG. 6 are merely exemplary. Other electronic devices may also include the device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-6 may be rearranged and/or combined into a single component, process, feature or function or embodied in several components, processes, or functions. Additional elements, components, processes, and/or functions may also be added without departing from the disclosure. In some implementations, FIGS. 1-6 and their corresponding description may be used to manufacture, create, provide, and/or produce hybrid cooling systems and/or devices including hybrid cooling systems.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X2’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a first portion, a second portion moveably coupled to the first portion via a junction, and a cooling loop structure. The cooling loop structure includes a fluid transport structure and a fluid driving structure coupled to the fluid transport structure. The fluid driving structure is configured to move a fluid through the fluid transport structure. The fluid transport structure extends into the first portion, into the second portion, and across the junction to enable heat distribution between the first portion and the second portion.

Example 2 includes the device of Example 1, wherein the device is a foldable device.

Example 3 includes the device of Example 2, wherein the foldable device is a smartphone.

Example 4 includes the device of any of Examples 1 to 3, wherein the first portion is configured to generate more heat than the second portion during operation, and wherein the cooling loop structure is configured to distribute at least some of the heat from the first portion to the second portion via movement of the fluid.

Example 5 includes the device of any of Examples 1 to 4, wherein the fluid comprises atmospheric air.

Example 6 includes the device of any of Examples 1 to 4, wherein the fluid comprises a non-gaseous fluid.

Example 7 includes the device of any of Examples 1 to 6, wherein the fluid transport structure is formed substantially from plastic.

Example 8 includes the device of any of Examples 1 to 6, wherein the fluid transport structure comprises a first fluid transport portion substantially within the first portion, a second fluid transport portion substantially within the second portion, and a junction fluid transport portion substantially within the junction, wherein the junction fluid transport portion is flexible.

Example 9 includes the device of any of Examples 1 to 8, wherein the fluid transport structure is formed in a substantially continuous loop.

Example 10 includes the device of any of Examples 1 to 9, wherein the second portion is foldably coupled to the first portion via the junction.

Example 11 includes the device of any of Examples 1 to 10 and further includes a foldable display coupled to the first portion, the second portion, and the fluid transport structure.

Example 12 includes the device of any of Examples 1 to 11, wherein the first portion comprises a middle frame.

Example 13 includes the device of Example 12, wherein the middle frame is composed substantially of aluminum.

Example 14 includes the device of Example 12 or Example 13, wherein the fluid transport structure is coupled to a surface of the middle frame.

Example 15 includes the device of Example 12 or Example 13, wherein a portion of the fluid transport structure within the first portion is embedded within the middle frame.

According to Example 16, a cooling loop structure includes a fluid transport structure and a fluid driving structure coupled to the fluid transport structure and configured to move a fluid through the fluid transport structure. The fluid transport structure includes a first fluid transport portion configured to be positioned in a first portion of a device and a second fluid transport portion configured to be positioned in a second portion of the device. The second portion is moveably coupled to the first portion via a junction. The fluid transport structure also includes a third fluid transport portion configured to be positioned in the junction.

Example 17 includes the cooling loop structure of Example 16, wherein the third fluid transport portion is flexible.

Example 18 includes the cooling loop structure of Example 16 or Example 17, wherein the fluid transport structure is formed in a substantially continuous loop.

According to Example 19, a method includes forming a fluid transport structure and forming a fluid driving structure coupled to the fluid transport structure and configured to move a fluid through the fluid transport structure. The fluid transport structure includes a first fluid transport portion configured to be positioned in a first portion of a device and a second fluid transport portion configured to be positioned in a second portion of the device. The second portion is moveably coupled to the first portion via a junction. The fluid transport structure also includes a third fluid transport portion configured to be positioned in the junction.

Example 20 includes the method of Example 19, further includes forming the first portion of the device; and forming the second portion of the device, wherein the second portion is moveably coupled to the first portion via a junction.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a first portion;
a second portion moveably coupled to the first portion via a junction;
a cooling loop structure comprising:
a fluid transport structure; and
a fluid driving structure coupled to the fluid transport structure and configured to move a fluid through the fluid transport structure, wherein the fluid transport structure extends into the first portion, into the second portion, and across the junction to enable heat distribution between the first portion and the second portion.

2. The device of claim 1, wherein the device is a foldable device.

3. The device of claim 2, wherein the foldable device is a smartphone.

4. The device of claim 1, wherein the first portion is configured to generate more heat than the second portion during operation, and wherein the cooling loop structure is configured to distribute at least some of the heat from the first portion to the second portion via movement of the fluid.

5. The device of claim 1, wherein the fluid comprises atmospheric air.

6. The device of claim 1, wherein the fluid comprises a non-gaseous fluid.

7. The device of claim 1, wherein the fluid transport structure is formed substantially from plastic.

8. The device of claim 1, wherein the fluid transport structure comprises a first fluid transport portion substantially within the first portion, a second fluid transport portion substantially within the second portion, and a junction fluid transport portion substantially within the junction, wherein the junction fluid transport portion is flexible.

9. The device of claim 1, wherein the fluid transport structure is formed in a substantially continuous loop.

10. The device of claim 1, wherein the second portion is foldably coupled to the first portion via the junction.

11. The device of claim 1, further comprising a foldable display coupled to the first portion, the second portion, and the fluid transport structure.

12. The device of claim 1, wherein the first portion comprises a middle frame.

13. The device of claim 12, wherein the middle frame is composed substantially of aluminum.

14. The device of claim 12, wherein the fluid transport structure is coupled to a surface of the middle frame.

15. The device of claim 12, wherein a portion of the fluid transport structure within the first portion is embedded within the middle frame.

16. A cooling loop structure comprising:
a fluid transport structure comprising:
a first fluid transport portion configured to be positioned in a first portion of a device;
a second fluid transport portion configured to be positioned in a second portion of the device, wherein the second portion is moveably coupled to the first portion via a junction; and
a third fluid transport portion configured to be positioned in the junction; and
a fluid driving structure coupled to the fluid transport structure and configured to move a fluid through the fluid transport structure.

17. The cooling loop structure of claim 16, wherein the third fluid transport portion is flexible.

18. The cooling loop structure of claim 16, wherein the fluid transport structure is formed in a substantially continuous loop.

19. A method comprising:
forming a fluid transport structure comprising:
a first fluid transport portion configured to be positioned in a first portion of a device;
a second fluid transport portion configured to be positioned in a second portion of the device, wherein the second portion is moveably coupled to the first portion via a junction; and
a third fluid transport portion configured to be positioned in the junction; and
forming a fluid driving structure coupled to the fluid transport structure and configured to move a fluid through the fluid transport structure.

20. The method of claim 19, further comprising:
forming the first portion of the device; and
forming the second portion of the device, wherein the second portion is moveably coupled to the first portion via a junction.
